(19) United States
(12) Patent Application Publication
(10) Pub. No.: US 2009/0063921 A1
(43) Pub. Date: Mar. 5, 2009

(54) Staggered LBIST Clock Sequence for Noise (di/dt) Amelioration

(76) Inventors: Anthony Gus Aipperspach, Rochester, MN (US); Louis Bernard Bushard, Rochester, MN (US); Dennis Thomas Cox, Rochester, MN (US)

Correspondence Address: IBM CORPORATION, 3605 HIGHWAY 52 NORTH, DEPT 917, ROCHESTER, MN, 55901-7829, US

(21) Appl. No.: 11/845,829

(22) Filed: Aug. 28, 2007

(51) Int. Cl. G06F 11/27; G01R 31/3187

(52) U.S. Cl. 714/733; 714/E11.169

(57) ABSTRACT

A method, device and system for performing on-chip testing are presented. In particular, the present invention provides a method, device and system for reducing noise due to large changes in current that occur during logical built-in self testing (LBIST) operations in integrated circuits. The method includes executing a first logical built-in self test sequence for a first logic region within an integrated circuit, subsequently executing a second logical built-in self test sequence for a second logic region within the integrated circuit, wherein the second test sequence is offset from the first test sequence by one or more clock cycles.

### FIELD OF THE INVENTION

The present invention relates in general to the field of integrated circuits and similar technologies, and in particular to built-in self testing of integrated circuits and similar technologies.

### DESCRIPTION OF THE RELATED ART

Traditional methods of testing semiconductor devices are quickly becoming obsolete. The use of functional patterns derived for design verification as manufacturing test patterns is becoming increasingly unacceptable. Some of the most severe problems associated with this approach are high test development times, defect coverages that are low or hard to measure, and poor diagnosability. Therefore test techniques were developed which based analysis on the design structure rather than on functionality.

The largest problem with both the functional and design structure based test techniques is their reliance on the use of automatic test equipment (ATE) to apply the test patterns to the device's external inputs and measure responses on the device's external outputs. This approach does not provide a means to adequately detect all of the device's internal defects. Direct access to the internal structures of a device is necessary. This requirement has led to the development of design-for-test (DFT) and built-in self-test (BIST) techniques and methods.

DFT techniques consist of design rules and constraints aimed at increasing the testability of a design through increased internal controllability and observability. The most popular form of DFT is scan design, which involves modifying all internal storage elements such that in test mode they form individual stages of a shift register for scanning in test data stimuli and scanning out test responses.

The BIST approach is based on the realization that much of a circuit tester's electronics is semiconductor-based, just like the products it is testing, and that the challenge in ATE design, and many of the emerging limitations in ATE-based testing, lies in the interface to the device under test. In light of this fact, the BIST approach can be described as an attempt to move many of the already semiconductor-based test equipment functions into the products under test and eliminate the complex interfacing. This embedding of functionality has many benefits.

Logic built-in self-test (LBIST) is used for manufacturing test at all package levels and for system self-test. The basic idea in LBIST is to add a pseudorandom-pattern generator (PRPG) to the inputs and a multiple-input shift register (MISR) to the outputs of the device's internal storage elements, which are arranged to form scan chains known as STUMPS channels. The acronym “STUMPS” stands for Self-Test Using MISR and PRPG Sequence. Pseudorandom patterns are applied to the logic under test by scanning the pseudorandom pattern into STUMPS channels (known as “channel fill”) and executing a test sequence that consists of scan and functional clock cycles. An LBIST controller generates all necessary waveforms for repeatedly loading pseudorandom patterns into the scan chains, initiating a functional cycle, and logging the captured responses out into the MISR. The MISR compresses the accumulated responses into a code known as a signature. Any corruption in the final signature at the end of the test indicates a defect in the chip.

System LBIST operation has historically been one of the highest power drain events in the operation of a microchip. This is primarily due to the high number of latches that are switching during the scan operations. The pseudorandom patterns have the feature that, on average, 50% of the latches exercised during scan are switching. The switching during channel fill creates a high demand for current on the cycle of the scan, causing a high change in current (i.e., di/dt) within the device. In turn, the rapid change in current leads to a voltage droop within the device. In the past, the channel fill problem was addressed by simply scanning the STUMPS channels at a lower rate. The lower rate was accomplished in several different ways, depending on the clocking. In one instance, the clocking style for scan is the well-known Level-Sensitive-Scan-Design (“LSSD”) style of clocking, and the channel fill is accomplished by applying two clocks (A and B) at a slow rate. In another instance, the clock for all purposes, including scan, is a single clock and is sometimes called a General Scan Design (“GSD”) clock. In this instance, a lower scan rate is accomplished by applying hold cycles between scan cycles. Typically three hold cycles are applied, which results in a scan every four clock cycles and an average switching rate of 12.5%. A switching rate of 12.5% is more in line with the average switching rate that is observed in mission mode (the set of all operations performed by an electronic chip during normal system operation). However, the issue of switching during channel fill is only part of the problem leading to voltage droop. The greater problem leading to voltage droop is the execution of the test sequence itself. To highlight the difference, channel fill can be viewed as looping on the pattern “Scan, Hold, Hold, Hold”, while a typical test sequence is the pattern “Scan, Functional Load, Functional Load, Functional Load”. The number of “Functional Load” operations is related to the depth of non-scan latches in the design. A “Functional Load” generates more switching than a “Hold” operation, thus creating a greater voltage droop, than a “Hold” operation. There is a need in the art to address the problem of voltage droop associated with executing an LBIST test sequence.

### SUMMARY OF THE INVENTION

The present invention provides a method, device and system for performing on-chip testing. In particular, the present invention provides a method, device and system for reducing voltage droop which occurs during logical built-in self testing (LBIST) operations in integrated circuits. The voltage droop typically results from large changes in current (i.e., di/dt) that occur when many latches change state on the same clock cycle. LBIST operations are particularly susceptible to causing large changes in current, due to the fact that many latches change state on a given clock cycle. In accordance with one or more embodiments of the present invention, an LBIST test sequence in one region of logic is offset from other regions of logic. The method includes executing a first logical built-in self test sequence for a first logic region of an integrated circuit, and then executing a second logical built-in self test sequence for a second logic region of the integrated circuit, wherein the second test sequence is offset from the first test sequence by one or more clock cycles. By offsetting the LBIST test sequences, the number of latches that changes state on a given clock cycle are reduced, thereby reducing noise due to large changes in current.

The above, as well as additional purposes, features, and advantages of the present invention will become apparent in the following detailed written description.

### BRIEF DESCRIPTION OF THE DRAWINGS

The novel features believed characteristic of the invention are set forth in the appended claims. The invention itself, however, as well as a preferred mode of use, further purposes and advantages thereof, will best be understood by reference to the following detailed description of an illustrative embodiment when read in conjunction with the accompanying drawings, where:

FIG. 1 shows a exemplary block diagram of a portion of an integrated circuit, chip 100, suited for LBIST, as known in the prior art;

FIG. 2 is a block diagram depicting logic disposed between two exemplary STUMPS channels, as known in the prior art;

FIG. 3 is a block diagram depicting a closer view of an exemplary STUMPS channel 300 and clocking logic in accordance with one embodiment of the present invention; and

FIG. 4 shows a block diagram of chip logic 108 divided into four logic regions (417, 427, 437, 447) by LBIST controller 110.

### DETAILED DESCRIPTION OF THE PREFERRED EMBODIMENT

The present invention provides a method, device and system for reducing voltage droop that occurs during logical built-in self testing (LBIST) operations in integrated circuits. The voltage droop typically results from large changes in current (i.e., di/dt) that occur when many latches change state on the same clock cycle. LBIST operations are particularly susceptible to causing large changes in current, due to the fact that many latches change state on a given clock cycle. In accordance with one or more embodiments of the present invention, an LBIST test sequence in one region of logic within an integrated circuit is offset from other regions of logic within the integrated circuit. By offsetting the LBIST clock sequences, the number of latches that change state on a given clock cycle are reduced, thereby reducing noise due to large changes in current.

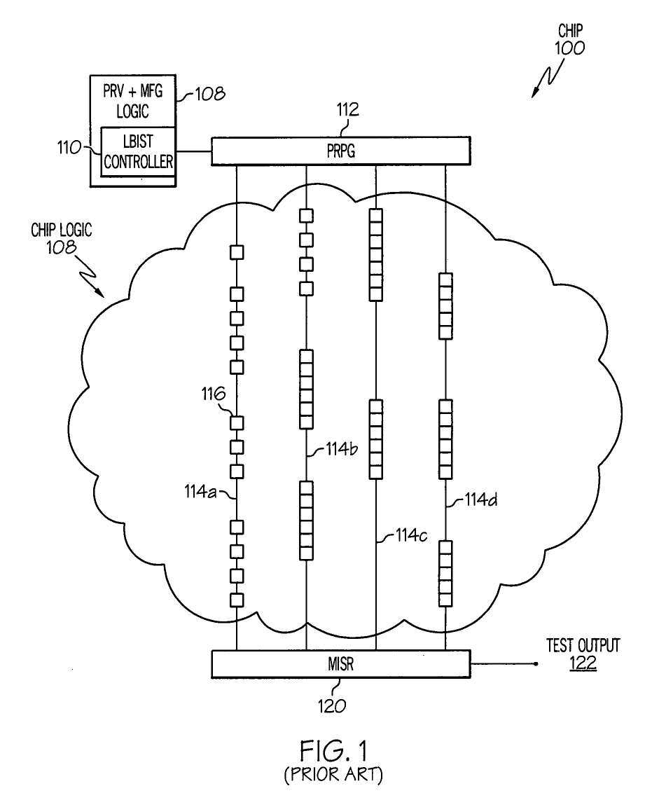

With reference now to the figures, wherein like numbers denote like parts throughout the several views, FIG. 1 shows an exemplary block diagram of a portion of an integrated circuit, chip 100, suited for LBIST, as known in the prior art. PRV & MFG logic 108 includes the logic that controls pervasive (PRV logic) functions like Power On Reset, Error Recovery, etc. The PRV logic controls LBIST functions such as scan and hold. Power On Reset can include an execution of LBIST as an option in a design. LBIST controller 110 MFG test logic includes the logic that supports manufacturing test (MFG logic) and is a natural extension of the pervasive logic. PRV & MFG logic 108 includes the logic that controls LBIST operation, LBIST controller 110.

LBIST controller 110 is coupled to a pseudorandom pattern generator (PRPG 112). During LBIST operation, PRPG 112 generates a pseudorandom data pattern that is scanned into all the latches of scan chains during the channel fill portion of the LBIST cycle. The scan chains are known as “STUMPS channels”, and are depicted in FIG. 1 as STUMPS channels 114a-d. Each STUMPS channel includes a number of shift register latches (SRLs) arranged in a serial chain. The SRLs of STUMPS channels 114a-d are disposed within chip logic 116. SRLs in single STUMPS channel feeds pseudorandom scan data from PRPG 112 into latches in the same STUMPS channel. Combinatorial logic and non-scanning latches are disposed between STUMPS channels 114a-d.

STUMPS channels 114a-d are coupled to a multiple input shift register, MISR 120. In typical LBIST operation, pseudorandom patterns are loaded into STUMPS channels 114a-d (“channel fill”), a functional cycle is initiated, and the captured responses are logged out of the STUMPS channels 114a-d into MISR 120. MISR 120 compresses the accumulated responses into a code known as a scan signature, which is scanned out of MISR 120 via test output 122. The scan signature obtained from the test is compared to a known-good scan signature that the functional logic of chip logic 108 should produce if operating properly.

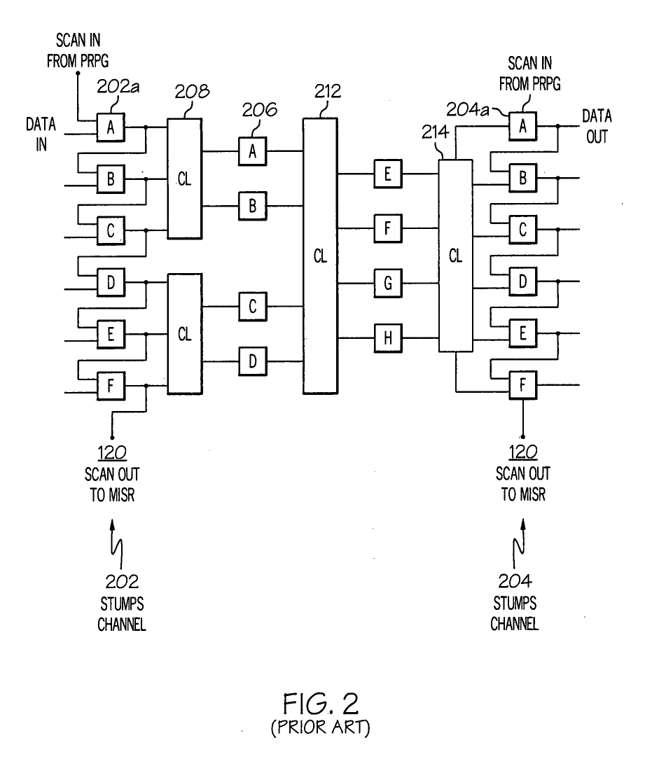

Referring now to FIG. 2, a block diagram depicting logic disposed between two STUMPS channels, as known in the prior art, is shown. STUMPS channel 202 includes scanning latches 202a-f. STUMPS channel 204 includes scanning latches 204a-f. Scan data from PRPG 112 is loaded into STUMPS channel 202 via the scan_in port of scanning latch 202a. Scan data from PRPG 112 is loaded into STUMPS channel 204 via the scan_in port of scanning latch 204a. With each successive scan clock, data from scanning latch 202a is loaded into scanning latch 202b, data from scanning latch 202b is loaded into scanning latch 202c, and so on. Likewise, with each successive scan clock, data from scanning latch 204a is loaded into scanning latch 204b, data from scanning latch 204b is loaded into scanning latch 204c, and so on. Scan clocks are applied until all the scanning latches in the STUMPS channels are filled with pseudorandom data from PRPG 112. This is known as “channel fill”.

The purpose of LBIST is to test that the intervening logic is functioning properly. This is accomplished by scanning pseudorandom data into one STUMPS channel (e.g., STUMPS channel 202) and executing a functional test sequence of the chip logic until the data reaches another STUMPS channel (e.g. STUMPS channel 204). STUMPS channel 202 and STUMPS channel 204 are coupled to each other by intervening combinatorial logic 208, 210, 212, 214 and non-scanning latches 206a-h. The functional test sequence is executed for the number of clock cycles it takes for the data scanned into STUMPS channel 202 to be processed by the intervening logic and reach STUMPS channel 204. Each clock executed during the functional testing is called a “functional load”. For the example shown in FIG. 2, it takes three functional loads after a scan to complete the functional test sequence. During the first clock cycle combinatorial logic 208 inputs data from scanning latches 202a-c and outputs data to non-scanning latches 206a-b. On the same clock cycle, combinatorial logic 210 inputs data from scanning latches 202d-f and outputs data to non-scanning latches 206. During the second clock cycle combinatorial logic 212 inputs data from non-scanning latches 206a-d and outputs data to non-scanning latches 206e-h. During the final clock cycle, combinatorial logic 214 inputs data from non-scanning latches 206e-h and outputs data to scanning latches 204a-f. At this point, the functional test sequence is complete and the data in STUMPS channel 204 can be read out to MISR 120 for analysis.

FIG. 2 shows only a few of the scanning latches included in a STUMPS channel. Typical integrated circuits with BIST features will have many more scanning latches in each STUMPS channel. When the pseudorandom patterns from the scanning latches are loaded during the first functional load, on average 50% of the latches will change state due the randomness of the pattern. If all of the latches are exercised on each clock cycle, the resulting large change in current leads to voltage droop. It is an object of the present invention to reduce voltage droop due to large current changes by offsetting the test sequence in one region of logic from another region of logic. Offsetting the test sequence in one region of logic from another region of logic substantially reduces the number of latches that are changing state on a given clock cycle, thereby reducing the overall change in current for that clock cycle.

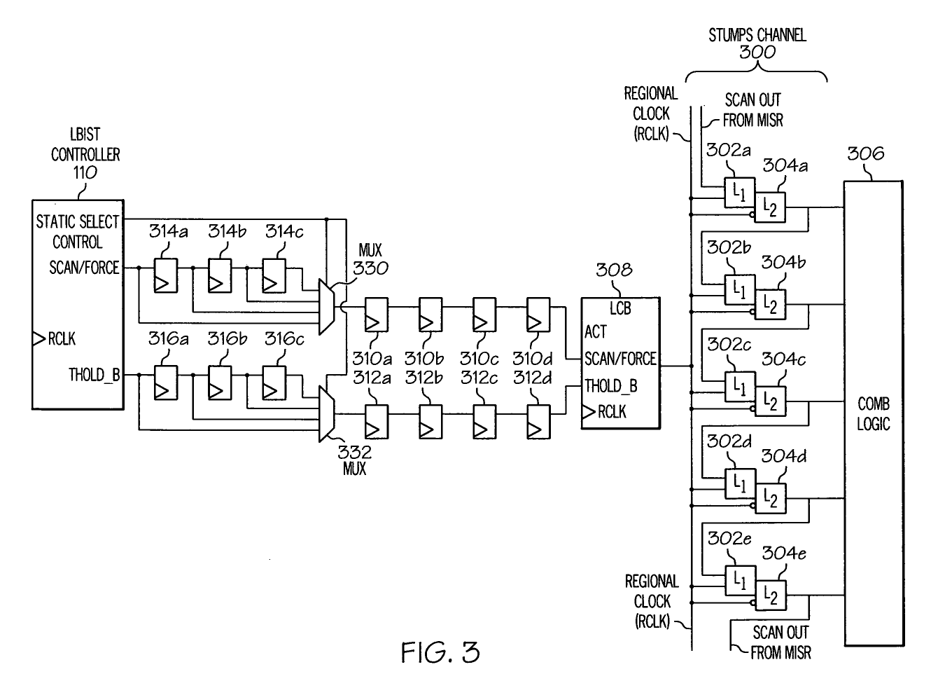

Referring now to FIG. 3, a block diagram depicting a closer view of an exemplary STUMPS channel 300 and clocking logic in accordance with one embodiment of the present invention. STUMPS channel 300 is comprised of a number of scanning latches. In one embodiment of the present invention, the scanning latches are arranged as depicted in FIG. 3. L1 latches 302a-e and L2 latches 304a-e are coupled so that the output of an L1 latch is the input to a corresponding L2 latch. For example, the output of L1 latch 302a is the input to L2 latch 304a. The output of L2 latch 304a feeds the scan input of the next L1 latch in the scan chain, L1 latch 302b. The output of L2 latch 304a also feeds adjacent combinatorial logic 306 for LBIST testing. The clocking of L1 latches 302a-e and L2 latches 304a-e is controlled by a local clock buffer (LCB 308). While only 5 latch pairs are shown in FIG. 3, LCB 308 can control the clock signals for any number of latch pairs. LCB 308 includes three input ports. The thold_b port is dominant. If this port is 0, then the output of LCB 308 (and the clock to L1 latches 302a-e) remains high and the clock to L2 latches 304a-e does not rise. If thold_b is 1, then the act or scan/force ports take control. If the L1/L2 pair constitutes a scan latch (SL) for LBIST testing, then the scan/force port is dominant and scan data is loaded, not functional data. If the L1/L2 pair constitutes a non-scan latch (NSL), the scan/force port is used to force a load of functional data into the latch pair. The target function of the act port is power savings, i.e., the act port is set to 0 on inactive functional cycles for the target latch pair. The act port can be used as a functional hold signal, as well as for power savings on inactive cycles.

The scan/force and thold_b signals that control LCB 308 originate from LBIST controller 110. LCB 308 and LBIST controller 310 are coupled together by the intervening logic shown in FIG. 3. A number of flush latches 310a-d, 312a-d, is coupled to LCB 308 for purposes of synchronization and fanout. Flush latches 310a-d are arranged in a tree forming the scan/force signal path. Flush latches 312a-d are arranged in an equal depth tree forming the thold_b signal path. Flush latches 310a-d, 312a-d are free-running and tap off the main clock grid or mesh (“nclk”). Multiple clocks are not needed to offset the test sequence in one region of logic from another region of logic. LBIST controller 110, LCB 308 and flush latches 310a-d, 312a-d, 314a-c, 316a-c can be clocked from a single clock signal, nclk, as shown in FIG. 3 by the common clock triangles. While four flush latches are shown for each exemplary tree in FIG. 2, any number may be used according to design requirements.

In accordance with one embodiment of the present invention, offsetting the test sequence in one region of logic within chip 100 from another region of logic within chip 100 is enabled by multiplexing the scan/force signal between flush latches 314a-c and by multiplexing the thold_b signal between flush latches 316a-c. A multiplexer, MUX 330, is coupled to flush latch 310a. MUX 330 is shown in FIG. 3 as having four inputs, but MUX 330 can have any number of inputs according to design requirements. The inputs to MUX 330 originate from the scan/force port of LBIST controller 110. The static_select_control of LBIST controller 110 selects the input of MUX 330 that feeds the tree of flush latches staring with flush latch 310a. Inputs to MUX 330 are delayed by one clock cycle relative to an adjacent input due to an additional intervening flush latch. For example, Input_0 of MUX 330 is taken directly from the scan/force port of LBIST controller 110. Between the electrical nodes for Input_0 and Input_1 of MUX 330 is flush latch 314a. The scan/force signal at Input_1 will be delayed one clock cycle relative to Input_0 due the extra clock cycle required to clock flush latch 314a. Likewise, between the electrical nodes for Input_1 and Input_2 of MUX 330 is flush latch 314b. The scan/force signal at Input_2 will be delayed one clock cycle relative to Input_1 due the extra clock cycle required to clock flush latch 314a. The scan force signal at Input_2 will be delayed two clock cycles relative to Input_0 due the two extra clock cycles required to clock flush latch 314a and then flush latch 314b. Likewise, between the electrical nodes for Input_2 and Input_3 of MUX 330 is flush latch 314c. The scan/force signal at Input_3 will be delayed one clock cycle relative to Input_2 due the extra clock cycle required to clock flush latch 314c. The scan force signal at Input_3 will be delayed two clock cycles relative to Input_1 due the two extra clock cycles required to clock flush latch 314b and then flush latch 314c. The scan force signal at Input_3 will be delayed three clock cycles relative to Input_0 due the three extra clock cycles required to clock flush latch 314a, then flush latch 314b and then flush latch 314c. MUX 332 is coupled to flush latch 312a and offsets the thold_b signal in a similar manner.

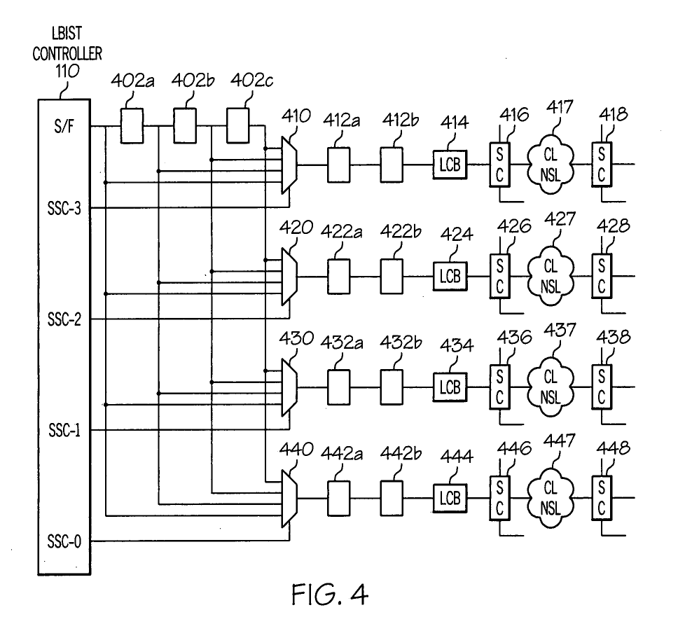

By multiplexing the signal paths between LBIST controller 110 and LCB 308 in the manner described above, LBIST controller 110 can divide chip logic 108 into several different logic regions by asserting a different static_select_control (SSC) bit for each logic region. FIG. 4 shows a block diagram of chip logic 108 divided into four logic regions (417, 427, 437, 447) by LBIST controller 110. While four logic regions are shown in the exemplary embodiment of FIG. 4 for purpose of illustration, chip logic 108 can be designed so that chip logic 108 can be divided into any number of logic regions. LBIST controller 110 is coupled to four LCBs 414, 424, 434, 444 by equal depth scan/force trees of flush latches (similar logic exists for thold_b trees, but is not shown). LBIST controller 110 assigns a unique value to each of the static select controls (SSC_0, SSC_1, SSC_2, SSC_3) at the time chip control is set to enforce the LBIST structure. As a result, the scan/force signal at each LCB (414, 424, 434, 444) is offset by a delay that is unique for the corresponding logic region. Each LCB will clock its corresponding STUMPS channels (416, 418, 426, 428, 436, 438, 446, and 448) with a pattern that is offset from the other LCBs. Instead of all logic regions performing functional loads of the same pseudorandom data at the same time, each logic region will have a different clocking pattern, thereby staggering the functional loads and reducing the number of latches that switch on a given cycle. This embodiment has the advantage of staggering channel fill as well. The logic in the FIG. 4 also exists on the thold_b trees between LBIST controller 110 and each LCB and is similarly controlled.

The use of multiplexers enables a chip tester to change the offset for a particular logic region by configuring the static select control bits for each logic region. The particular setting of the static select controls can be chosen by different criteria. One criterion could be based on the results of measurements of voltage droop during manufacturing or laboratory test, where various settings can be experimented with. Another criterion could be a priori estimates of voltage droop with various settings of static select controls.

The embodiment of FIG. 4 shows the selection of logic regions taking place at the root of the unique scan/force (and thold_b) trees from LBIST controller 110, where the branches emanate to unique logic regions. In an alternative embodiment, the selection of logic regions is implemented at an intermediate branch level, where the branches emanate to unique logic regions.

Another embodiment includes assigning unique scan/force (and thold_b) trees to carefully selected sets of STUMPS channels. The STUMPS channels in a set can be chosen by the following criteria: place two STUMPS channels in the same set of STUMPS channels if there is significant logic between the latches in the two channels. This choice enhances coverage. For example, if logic region 417 and logic region 427 comprise a significant amount of the same logic, then SSC_3 and SSC_2 can be set to the same value. This places STUMPS channel 416 and STUMPS channel 426 in the same set. Since they share much of the same logic, executing a functional test sequence of both STUMPS channels at the same time may generate less switching than executing a functional test sequence for each STUMPS channel at offset clock cycles.

While the present invention has been particularly shown and described with reference to an illustrative embodiment, it will be understood by those skilled in the art that various changes in form and detail may be made therein without departing from the spirit and scope of the invention. Furthermore, as used in the specification and the appended claims, the term “logic” or “device” or “system” includes any electronic circuit, or combination thereof, used in a data processing system, including, but not limited to, a microprocessor, microcontroller or component circuit integrated therein.

The diagrams in the Figures illustrate the architecture, functionality, and operation of possible implementations of methods, devices and systems according to various embodiments of the present invention. In this regard, each block in the diagrams may represent a module, circuit, or portion of a circuit, which comprises one or more functional units for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described the invention of the present application in detail and by reference to illustrative embodiments thereof, it will be apparent that modifications and variations are possible without departing from the scope of the invention defined in the appended claims.

What is claimed is:

1. A method for performing on-chip testing comprising:
executing a first logical built-in self test sequence for a first logic region within an integrated circuit;
subsequently executing a second logical built-in self test sequence for a second logic region within the integrated circuit; and
wherein the second test sequence is offset from the first test sequence by one or more clock cycles.

2. The method of claim 1, wherein the second test sequence is offset from the first test sequence by setting a configurable static select control bit.

3. The method of claim 2, wherein the static select control bit is used to select an input to a local clock buffer from a plurality of multiplexed inputs.

4. The method of claim 3, wherein each of the plurality of multiplexed inputs is offset from the other multiplexed inputs by one or more clock cycles.

5. The method of claim 1, wherein two or more STUMPS channels are assigned to the same logic region if there is significant logic in common between said two or more STUMPS channels.

6. The method of claim 1, wherein the selection of logic regions is implemented at the root level of trees branching from an LBIST controller to a plurality of local clock buffers.

7. The method of claim 1, wherein the selection of logic regions is implemented at an intermediate branch level of trees branching from an LBIST controller to a plurality of local clock buffers.

8. A device for performing on-chip testing comprising:
logic for executing a first logical built-in self test sequence for a first logic region within an integrated circuit;
logic for subsequently executing a second logical built-in self test sequence for a second logic region within the integrated circuit; and
wherein the second test sequence is offset from the first test sequence by one or more clock cycles.

9. The device of claim 8, further comprising logic for setting a configurable static select control bit, wherein the second test sequence is offset from the first test sequence by setting said configurable static select control bit.

10. The method of claim 9, further comprising logic for selecting an input to a local clock buffer from a plurality of multiplexed inputs, wherein the static select control bit is used for selecting an input to a local clock buffer from a plurality of multiplexed inputs.

11. The method of claim 10, wherein each of the plurality of multiplexed inputs is offset from the other multiplexed inputs by one or more clock cycles.

12. The device of claim 8, further comprising logic for assigning two or more STUMPS channels to the same logic region if there is significant logic in common between said two or more STUMPS channels.

13. The device of claim 8, further comprising logic for selecting logic regions, wherein said logic is implemented at the root level of trees branching from an LBIST controller to a plurality of local clock buffers.

14. The device of claim 8, further comprising logic for selecting logic regions, wherein said logic is implemented at an intermediate branch level of trees branching from an LBIST controller to a plurality of local clock buffers.

15. A system for performing on-chip testing comprising:
at least one processor;
a memory coupled to said at least one processor;
logic for executing a first logical built-in self test sequence for a first logic region within an integrated circuit;
logic for subsequently executing a second logical built-in self test sequence for a second logic region within the integrated circuit; and
wherein the second test sequence is offset from the first test sequence by one or more clock cycles.

16. The system of claim 15, further comprising logic for setting a configurable static select control bit, wherein the second test sequence is offset from the first test sequence by setting said configurable static select control bit.

17. The system of claim 16, further comprising logic for selecting an input to a local clock buffer from a plurality of multiplexed inputs, wherein the static select control bit is used for selecting an input to a local clock buffer from a plurality of multiplexed inputs.

18. The system of claim 17, wherein each of the plurality of multiplexed inputs is offset from the other multiplexed inputs by one or more clock cycles.

19. The system of claim 15, further comprising logic for assigning two or more STUMPS channels to the same logic region if there is significant logic in common between said two or more STUMPS channels.

20. The system of claim 15, further comprising logic for selecting logic regions, wherein said logic is implemented at an intermediate branch level of trees branching from an LBIST controller to a plurality of local clock buffers.
